(19) United States
(12) Patent Application Publication
(10) Pub. No.: US 2024/0063604 A1
(43) Pub. Date: Feb. 22, 2024

(54) OPTICAL FIBER RING RESONATOR AND OPTICAL FIBER RING RESONATOR-BASED LASER STABILIZATION APPARATUS AND METHOD

(71) Applicant: Korea Advanced Institute of Science and Technology, Daejeon (KR)

(72) Inventors: Jungwon KIM, Daejeon (KR); Igju Jeon, Daejeon (KR); Changmin Ahn, Daejeon (KR)

(21) Appl. No.: 18/232,927

(22) Filed: Aug. 11, 2023

(30) Foreign Application Priority Data
Aug. 17, 2022 (KR) 10-2022-0102462
Apr. 7, 2023 (KR) 10-2023-0046243

(51) Int. Cl. H01S 5/0687; H01S 5/183; G01J 1/02; G01J 1/04

(52) U.S. Cl. CPC H01S 5/0687; H01S 5/18355; G01J 1/0228; G01J 1/0238; G01J 1/0425

(57) ABSTRACT

Provided is a laser stabilization apparatus including an optical fiber resonator that is in the form of an optical fiber loop with an optical fiber delay-line, and is designed to resonate at a stabilized frequency of a laser, wherein when light emitted from the laser is input to the optical fiber resonator, a transmittance thereof changes according to a frequency of the input light, and a light measurer configured to measure light output from the optical fiber resonator and generate an error signal for stabilizing a frequency of the laser.

### CROSS-REFERENCE TO RELATED APPLICATION

This application claims priority to and the benefit of Korean Patent Application No. 10-2022-0102462 filed in the Korean Intellectual Property Office on Aug. 17, 2022, Korean Patent Application No. filed in the Korean Intellectual Property Office on, and Korean Patent Application No. 10-2023-0046243 filed in the Korean Intellectual Property Office on Apr. 7, 2023, the entire contents of which are incorporated herein by reference.

### BACKGROUND

### (a) Field

The present disclosure relates to a laser stabilization apparatus.

### (b) Description of the Related Art

Ultra-stable lasers are critical to many fields that require extremely stable frequency references, such as optical lattice clocks, gravitational wave detection, precision spectroscopy. The ultra-stable lasers may be used to generate ultra-stable microwaves through optical frequency division, which can improve the performance of various microwave photonic applications including radio astronomy and radar systems. In addition, there is a growing demand for more compact, robust and portable ultra-stable laser systems operating in non-laboratory environment.

Stabilizing a laser may involve using an optical cavity with a high Q-factor. While this method offers advantageous performance, it requires a large-scale and expensive system, making it challenging to achieve excellent performance in a non-laboratory environment. In addition, a setup of this method is inherently complicated, thus making it difficult to realize miniaturization and efficient packaging.

Alternatively, an optical fiber delay-line is used to stabilize the laser using a self-heterodyne method. However, the self-heterodyne stabilization method has some drawbacks. It additionally requires a frequency modulator for heterodyne detection. To achieve a high Q-factor, a relatively long optical fiber, such as 1 km or more, is necessary.

### SUMMARY

The present disclosure attempts to provide an optical fiber ring resonator and an optical fiber ring resonator-based laser stabilization apparatus and method.

An exemplary embodiment of the present disclosure provides laser stabilization apparatus including: an optical fiber resonator which is in the form of an optical fiber loop with an optical fiber delay-line, wherein when light emitted from a laser is input to the optical fiber resonator, a transmittance of the optical fiber resonator changes according to a frequency of the input light; and a light measurer configured to measure light transmitted through the optical fiber resonator and generate an error signal for stabilizing a frequency of the laser.

The light measurer may include a balanced photodetector. The balanced photodetector may include a first photodiode and a second photodiode, and be configured to measure the intensity difference between target light to be measured, which is input to the first photodiode, and reference light input to the second photodiode, and output the error signal. The light emitted from the laser may be divided into two components, and one component may enter the second photodiode and the other component may enter the optical fiber resonator, and light output from the optical fiber resonator may enter the first photodiode.

The balanced photodetector may offset noise contained in both the reference light and the target light using balanced optical detection, and detect frequency noise of the laser.

The optical fiber resonator may be implemented as a polarization-maintaining fiber.

The frequency of the laser may be locked at a frequency to maintain the error signal at a specific value.

The laser stabilization apparatus may further include a feedback controller configured to transmit the error signal to a piezoelectric transducer of the laser.

The laser stabilization apparatus may further include a feedback controller configured to transmit the error signal to a modulator that modulates an output of the laser.

Another exemplary embodiment of the present disclosure provides a laser stabilization apparatus including: an optical coupler configured to divide light emitted from a laser into first light and second light and output the first light and the second light; an optical fiber ring resonator configured to divide the first light into third light and fourth light using an unbalanced optical coupler, make the third light entering a ring type optical fiber loop to pass through an optical fiber delay-line of the optical fiber loop, and output the fourth light to outside of the optical fiber loop; and a balanced photodetector configured to output an error signal corresponding to the intensity difference between the fourth light and the second light. The error signal may be fed back to the laser, and a frequency of the laser may be locked at a frequency to maintain the error signal at a specific value.

The frequency of the laser may be determined by a transmittance of the optical fiber ring resonator.

A Q-factor of the optical fiber ring resonator may be calculated, based on a coupling ratio of the unbalanced optical coupler and a length of the optical fiber delay-line.

The optical fiber ring resonator may further include an optical isolator configured to guide light toward a circulation direction in the optical fiber loop.

The optical fiber ring resonator may be implemented as a polarization-maintaining fiber.

The balanced photodetector may include a first photodiode to which the fourth light passing through the optical fiber ring is input and a second photodiode to which the second light is input, and be configured to convert the intensity difference between the fourth light and the second light into an electrical signal, and output the error signal corresponding to the electrical signal.

The balanced photodetector may offset noise contained in both the second light and the fourth light using balanced optical detection, and detect frequency noise of the laser.

The laser stabilization apparatus may further include a feedback controller configured to transmit the error signal to a piezoelectric transducer of the laser.

The laser stabilization apparatus may further include a feedback controller configured to transmit the error signal to a modulator that modulates an output of the laser.

Another exemplary embodiment of the present disclosure provides an operation method of a laser stabilization apparatus including: dividing light emitted from a laser into target light to be measured and reference light; making light coupled from the target light enter an optical fiber ring resonator, and outputting the transmitting light that is not stored in the optical fiber ring resonator among the target light, to outside of the optical fiber ring resonator; and outputting an error signal corresponding to the intensity difference between the reference light and the transmitting light output from the optical fiber ring resonator using balanced optical detection. The optical fiber ring resonator may include an optical fiber delay-line.

The operation method may further include feeding back the error signal to the laser for stabilizing the frequency of the laser.

A transmittance of the optical fiber ring resonator may change according to a frequency of input light.

The operation method may further include offsetting noise contained in both the reference light and the transmitting light output from the optical fiber ring resonator using the balanced optical detection, and detecting frequency noise of the laser.

According to an embodiment, the utilization of an optical fiber ring resonator offers the advantages of employing the high Q-factor performance of an optical fiber delay-line, making no need for an additional modulator unlike the self-heterodyne method based on an optical fiber delay-line, and using of a very short delay line.

According to an embodiment, by using an optical fiber ring resonator, an error signal may be generated without the need for an additional modulator. This eliminates the requirement for a larger optical fiber spool to wind the fiber around, allowing for a more compact device size. Furthermore, using a shorter delay line enables an increase in a locking bandwidth limited by the length of a delay line.

According to an embodiment, the utilization of an optical fiber resonator that may be configured with passive devices simplifies a setup for laser stabilization, reduces the cost, and provides excellent frequency stabilization performance.

According to an embodiment, a frequency stabilization apparatus may be an all-fiber type system and thus is alignment-free, so that it can be applied even in a non-laboratory environment.

### BRIEF DESCRIPTION OF THE DRAWINGS

FIGS. 1 and 2 are diagrams for describing the concept of optical fiber delay-line-based laser stabilization.

FIG. 3 is a diagram for describing a self-heterodyne stabilization method using an optical filter delay-line.

FIG. 4 is a diagram for describing an optical fiber ring resonator-based laser stabilization apparatus according to an embodiment.

FIG. 5 illustrates a graph showing a transmittance of an optical fiber ring resonator according to an embodiment.

FIG. 6 illustrates an example of an optical fiber spool according to an embodiment.

FIG. 7 illustrates an overall configuration of a laser stabilization apparatus according to an embodiment.

FIG. 8 illustrates an operation method of a laser stabilization apparatus according to an embodiment.

FIG. 9 illustrates a result of measuring phase noise of a stabilized laser according to an embodiment.

FIG. 10 illustrates a result of measuring frequency instability of a stabilized laser according to an embodiment.

### DETAILED DESCRIPTION OF THE EMBODIMENTS

In the following detailed description, only certain exemplary embodiments of the present disclosure have been shown and described, simply by way of illustration. As those skilled in the art would realize, the described embodiments may be modified in various different ways, all without departing from the spirit or scope of the present disclosure. Accordingly, the drawings and description are to be regarded as illustrative in nature and not restrictive. Like reference numerals designate like elements throughout the specification.

In the following description, unless explicitly described to the contrary, the word “comprise”, and variations such as “comprises” or “comprising”, will be understood to imply the inclusion of stated elements but not the exclusion of any other elements.

In the following description, reference numerals and terms are given for convenience of description and thus devices are not necessarily limited thereby.

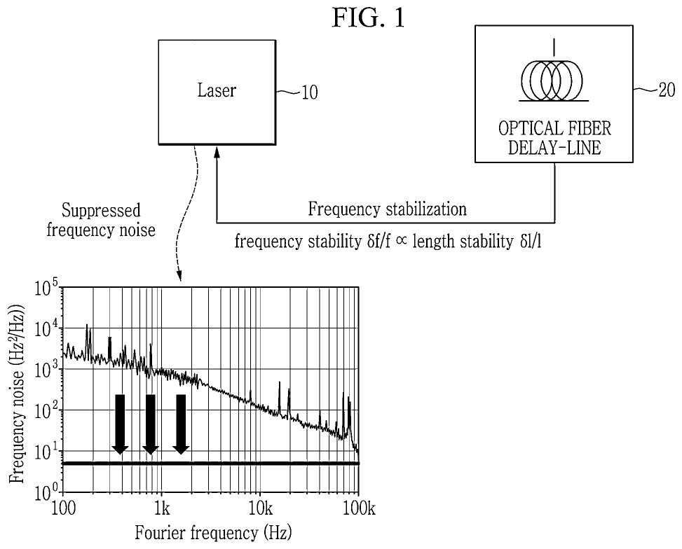

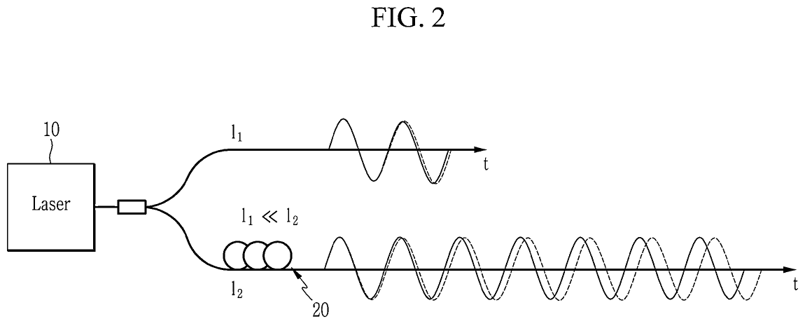

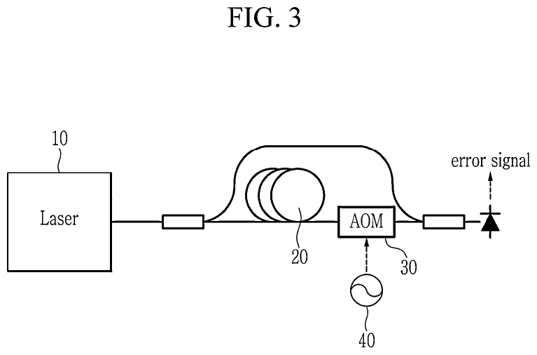

FIGS. 1 and 2 are diagrams for describing the concept of optical fiber delay-line-based laser stabilization. FIG. 3 is a diagram for describing a self-heterodyne stabilization method using an optical filter delay-line.

Referring to FIG. 1, a laser 10 may suppress laser noise for frequency stabilization. The laser 10 may be a continuous wave (CW) laser and include various types of well-known lasers, including an optical frequency comb, a Kerr micro-comb, etc.

A phase/frequency of laser output may vary according to noise originating from various causes. Therefore, noise may be suppressed by stabilizing the laser frequency according to an optical reference.

The laser 10 follows the stability of a relatively more stable reference, and an optical fiber delay-line 20 may be used as the optical reference. In this case, frequency stability δf/f follows length stability δl/l of the relatively more stable optical fiber delay-line.

Referring to FIG. 2, a signal output from the laser 10 is in the form of a sine wave and the phase of laser output may change due to frequency noise. As the signal moves for a longer time, the phase difference between the signal and the original signal increases and thus a reference signal moving in a short reference path (reference arm) and a signal moving in a delay path (delay arm) of the optical fiber delay-line 20 may be compared with each other to detect a phase difference related to frequency noise. Laser frequency noise may be suppressed using the detected phase difference.

Referring to FIG. 3, a representative laser stabilization method using an optical fiber delay-line is a self-heterodyne method, which uses a Michelson interferometer that interferes two signals passing through a reference path and a delay path. According to characteristics of the self-heterodyne method, a frequency modulator 30, such as an acousto-optic modulator (AOM), is used to shift a frequency of the signal passing through the delay path by using a frequency of an oscillator 40. The frequency modulator 30 may be referred to as an acousto-optic frequency shifter (AOFS).

Thus, in the self-heterodyne method, a modulator is additionally needed to shift a frequency, which imposes constraints on packaging size due to a modulator size. Additionally, a relatively long optical fiber (e.g., 1 km or more) is needed to achieve a high Q-factor (e.g., 10⁹).

An optical fiber ring resonator-based laser stabilization apparatus and method that supplement the disadvantages of the self-heterodyne method and improve optical fiber delay-line-based frequency stabilization will be described in detail below.

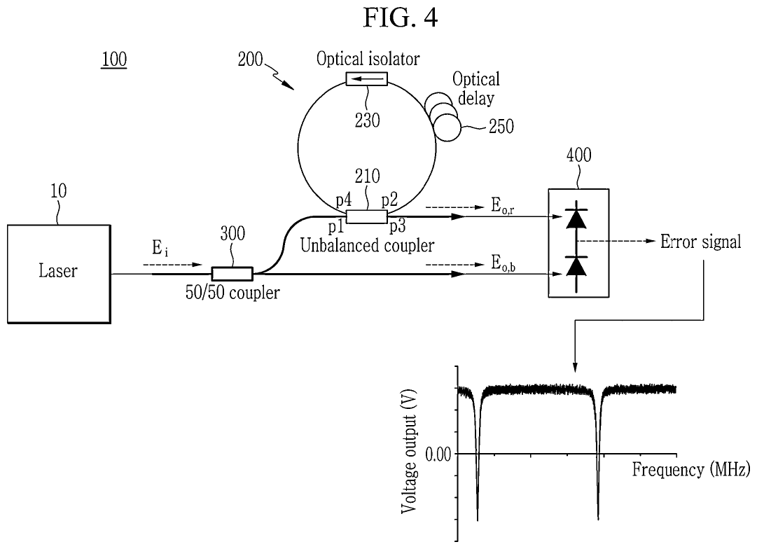

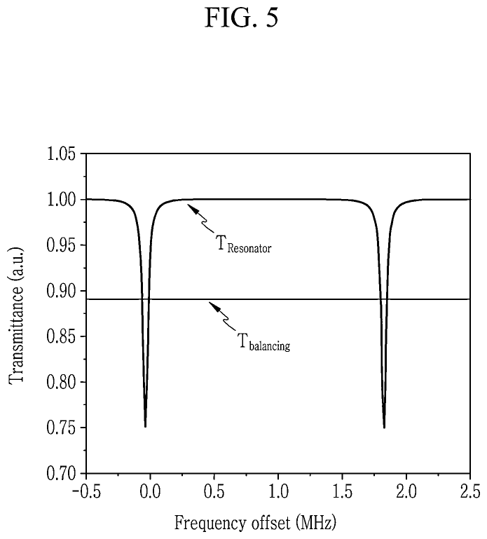

FIG. 4 is a diagram for describing an optical fiber ring resonator-based laser stabilization apparatus according to an embodiment. FIG. 5 illustrates a graph showing a transmittance of an optical fiber ring resonator according to an embodiment.

Referring to FIG. 4, a laser stabilization apparatus 100 is an apparatus that stabilizes a frequency of a laser 10, and includes an optical fiber ring resonator 200 designed to resonate at the stabilized frequency of the laser 10. The optical fiber ring resonator 200 is used as a frequency discriminator for laser stabilization.

The optical fiber ring resonator 200 may be designed to resonate only at a frequency corresponding to a length of the optical fiber ring resonator 200. That is, the optical fiber ring resonator 200 at a frequency at which the length of the optical fiber is an integer multiple of a half-wavelength of a laser. A laser with a frequency different from a resonant frequency does not resonate inside a resonator but is fully transmitted, resulting in a transmittance of 1. As the laser frequency gradually approaches the resonant frequency of the optical fiber ring resonator, a ratio of the laser output trapped in the resonator increases, causing the transmittance of the laser output to decrease gradually. The transmittance becomes minimum at a point at which the laser frequency becomes equal to the resonant frequency. By observing the point at which the transmittance of the optical fiber ring resonator changes according to the laser frequency, it is possible to calculate the change in laser frequency. Therefore, the optical fiber ring resonator 200 may act as a frequency discriminator. The frequency discrimination sensitivity of the resonator may be determined by the change in transmittance versus frequency, and as the sensitivity increases, a frequency may be detected more sensitively, leading to improved performance in laser stabilization. The sensitivity increases as a Q factor of the resonator increases.

As described above, the optical fiber ring resonator 200 may stores input light by resonating with the input light. The light that is not stored in the optical fiber ring resonator 200 is output to the outside. By observing the changes in the output light, it is possible to determine whether the frequency of the input light is a resonant frequency.

The optical fiber ring resonator 200 may include an unbalanced optical coupler 210, an optical isolator 230, and an optical fiber delay-line 250 corresponding to the length of an optical fiber, and may be connected in a ring shape to form a loop. To maximize the efficiency of detecting the interference signal, each components of the optical fiber ring resonator 200 may be implemented as polarization-maintaining fiber. Here, the transmittance of the optical fiber ring resonator 200 may be calculated as a ratio of the output light intensity E_{o,r} to the input light intensity Eᵢ, and a high Q-factor may be achieved at a resonant dip that occurs periodically.

The unbalanced optical coupler 210 functions by dividing the input light at different ratios (an imbalance ratio), directing it to both the optical fiber loop and the outside of the optical fiber loop. By employing a coupling ratio of 100−T:T, the unbalanced optical coupler 210 may allow T % of input light to enter the optical fiber loop. For example, when the unbalanced optical coupler 210 is designed with a coupling ratio of 99:1, 1% of the input light may be transmitted to the optical fiber loop. The coupling ratio may be changed variously.

The unbalanced optical coupler 210 may include two input terminals and two output terminals, and the two input terminals may be defined as a first port p1 and a fourth port p4 and the two output terminals may be defined as a second port p2 and a third port p3. Within this configuration, the unbalanced optical coupler 210 may include the first port p1 which receives the light output from the laser 10, the second and fourth ports p2 and p4 connected to both ends of the optical fiber loop, and the third port p3 which outputs divided light to the outside of the optical fiber loop. That is, one side of the optical fiber loop may be connected to the second port p2 of the unbalanced optical coupler 210 and another side thereof may be connected to the fourth port p4 of the unbalanced optical coupler 210 to form a ring.

For example, in a 99:1 coupler, 1% of light incident at the first port p1 is distributed to the second port p2, passes through the optical fiber loop, and is guided to the fourth port p4 which serves as an input terminal. According to an operating principle of a coupler, 99% of light incident on the fourth port p4 is coupled to the second port p2 and thus the majority of light incident on the coupler is trapped in the resonator. In this case, the length of a ring type optical fiber connected to the second port p2 and the fourth port p4 may be correspond to that of the resonator. Only when the length is an integer multiple of a half-wavelength 212 of the laser 10, laser light that rotate inside the resonator several times may resonate while the phases of laser light are coherent, enabling them to be trapped in the resonator. As described above, laser light with a frequency different from a resonant frequency does not resonate inside the resonator but is transmitted rather than being trapped. However, as the frequency of the laser gradually approaches the resonant frequency of the optical fiber ring resonator 200, the transmittance of the resonator gradually decreases to less than 1 and becomes minimum at a point at which the frequency becomes the same as the resonant frequency. The transmittance graph shows a similar shape to an error signal. By normalizing a voltage of the error signal on y-axis, it may be considered as a transmittance graph. Therefore, the transmittance and the error signal may be considered as corresponding values. By feeding back the error signal associated with a transmittance to the laser 10, the laser frequency may be locked a frequency matching a specific transmittance, thereby achieving laser stabilization. For example, in the absence of stabilization, laser frequency fluctuates randomly, causing the detected transmittance or error signal to vary between 1 and 0.7. By applying feedback control and maintaining the error signal at a value of 0.8, the laser 10 may be locked to a frequency corresponding to the error signal of 0.8 and thus be stabilized.

The optical isolator 230 is a device that guides light only in a direction of ring circulation, effectively preventing Brillouin backscattering.

The Q-factor of the optical fiber ring resonator 200 may be calculated, based on a coupling ratio of the unbalanced optical coupler 210, the length of the optical fiber delay-line 250, and an internal loss rate. With trapping most of the light within the resonator at the resonant frequency, a high Q-factor can be achieved. This allows for comparable Q-factor performance even with an optical fiber that is significantly shorter, perhaps even one-tenth the length, compared to the fiber used in the self-heterodyne method.

The laser stabilization apparatus 100 may further include a light measurer to measure a transmittance of the optical fiber ring resonator 200 and generate a signal for stabilizing the laser 10. The light measurer is configured to measure a transmittance of the optical fiber ring resonator 200 on the basis of input light and output light of the optical fiber ring resonator 200, and may measure a transmittance of the optical fiber ring resonator 200. This measurement can be performed using a balanced photo detection technique, ensuring accurate transmittance measurements. To this end, the laser stabilization apparatus 100 may further include an optical coupler 300 and a balanced photodetector 400. The optical coupler 300 may be a 50/50 coupler. For balanced photo detection, the optical coupler 300 may be used to divided laser output into two directions.

One light component divided from laser output by the optical coupler 300 passes through the optical fiber ring resonator 200 and then directed to a port (a positive port), referring to as a resonator port, of the balanced photodetector 400. The other light component, which serves as reference light that does not pass through the optical fiber delay-line, is directed to another port (a negative port), referring to as a balanced port, of the balanced photodetector 400. That is, the light entering the balanced port corresponds to the light entering the optical fiber ring resonator 200, while the light entering the resonator port is light output from the optical fiber ring resonator 200. Thus, the transmittance of the optical fiber ring resonator 200 may be measured by the balanced photodetector 400.

The balanced photodetector 400 may convert the intensity difference (E_{o,r}, E_{o,b}) between the light entering two photo diodes into an electrical signal, by using the two photo diodes and a differential amplifier, and output an error signal corresponding to the electrical signal. The balanced photodetector 400 may compare the light passing through the optical fiber ring resonator 200 with the reference light, and measure an error signal associated with frequency noise. As a laser frequency approaches the resonant frequency, the transmittance of the optical fiber ring resonator 200 decreases, resulting in an intensity difference between the light entering the resonator port and the balanced port, which may be measured through balanced photo detection.

The error signal generated by the balanced photodetector 400 may be fed back to the laser 10 to suppress frequency noise. Specifically, when the error signal is locked to 0 V through a servo mechanism, a frequency of the laser 10 is stabilized at a zero crossing frequency.

Laser intensity noise is commonly contained in light input to each port of the balanced photodetector 400. By using balanced photo detection to measure the intensity difference between the input light, the laser intensity noise may be cancelled out. Therefore, the laser intensity noise may be decoupled from frequency noise.

The balanced photodetector 400 may isolate the measurement of frequency noise from the laser intensity noise. By using balanced photodetection, the intensity noise can be decoupled from the error signal, which can only reflect the information of frequency variation of the laser. Thus, the frequency noise may not be completely suppressed by a laser to which an inaccurate error signal is fed back.

An operation of the laser stabilization apparatus 100 is as described below. First, the optical coupler 300 divides light output from the laser 10 into two components: first light and second light. The first light is directed to the optical fiber ring resonator 200, which is designed to resonate at the desired frequency of the laser 10. In the optical fiber ring resonator 200, the first light is further divided into third light and fourth light by the unbalanced optical coupler 210. The third light to be incident on a ring type optical fiber loop passes through an optical fiber delay-line on the optical fiber loop, while the fourth light is directed to the balanced photodetector 400 outside the optical fiber loop. The balanced photodetector 400 may generate an error signal corresponding to the intensity difference between the second light, which is reference light, and the fourth light to be measured. The error signal is fed back to the laser 10 for frequency stabilization. Here, when the laser frequency approaches the resonant frequency of the optical fiber ring resonator 200 due to the error signal, the portion of the third light coupled to the optical fiber loop and trapped in the optical fiber ring resonator 200 increases. Then, the transmittance of the optical fiber ring resonator 200 gradually decreases to less than 1 and becomes minimum at a point at which the laser frequency is the same as the resonant frequency. Accordingly, a change in the transmittance of the optical fiber ring resonator 200 may be observed through the fourth light and the laser frequency may be stabilized according to the change in the transmittance. That is, the detected error signal is related to the transmittance of the optical fiber ring resonator 200, and thus, when the error signal is fed back to the laser 10 to maintain the transmittance of the optical fiber ring resonator 200 at a specific value, the laser frequency may be locked to a frequency matching the desired transmittance, thus achieving laser stabilization.

Referring to FIG. 5, when the laser output is incident on the optical fiber ring resonator 200, a transmittance representing a ratio of the output light intensity E_{o,r} to the input light intensity Eᵢ according to the laser frequency may be expressed as a transmittance graph T_{Resonator}. A transmittance significantly changes even with a little change in a laser frequency at a resonant dip occurring periodically at intervals of a free spectral range (FSR) and thus a laser may be stabilized according to such sensitivity.

Meanwhile, the transmittance graph T_{balancing} of the balancing port is continuously |E_{o,b}/Eᵢ|² and a locking point of the error signal may be determined by a level of the balanced port.

As a coupling ratio of the unbalanced optical coupler 210 increases, the length of the optical fiber delay-line 250 increases, or a loss rate decreases, the Q-factor of the optical fiber ring resonator 200 increases. For example, with the coupling ratio of 99:1, the length of a delay line of 100 m, and an internal loss rate of 0.5 dB, the optical fiber ring resonator 200 may achieve a high Q-factor of approximately 4.5×10⁹. Compared to the self-heterodyne method, which requires several kilometers of delay line (e.g., 2.2 km) to achieve a similar Q-factor, the optical fiber ring resonator 200 may allow a significantly reduction in delay line length to 100 meters.

As described above, the laser stabilization apparatus 100 uses the optical fiber ring resonator 200, offering advantages such as the utilization of high Q-factor performance of the optical fiber delay-line without the need for an additional modulator as required in the self-heterodyne method based on an optical fiber delay-line. This allows for the use of a very short delay line. Because an error signal is generated using the optical fiber ring resonator 200, a modulator is not additionally needed, the size of an optical fiber spool around which an optical fiber is wound can be reduced, thus minimizing the size of a device. The locking bandwidth, which is typically limited by the length of a delay line can be increased. Actually, an optical fiber delay-line occupies largest volume in a resonator, and the volume of a 100 m optical fiber may be reduced to 10 mL or less. Thus, with an optical fiber ring resonator-based stabilization method, the limitation of the self-heterodyne method can be supplemented, and the benefits of an optical fiber delay-line can be maximized.

In addition, because the optical fiber resonator 200 that may be configured with passive devices is used, a setup for laser stabilization is simple and inexpensive and excellent frequency stabilization performance can be provided.

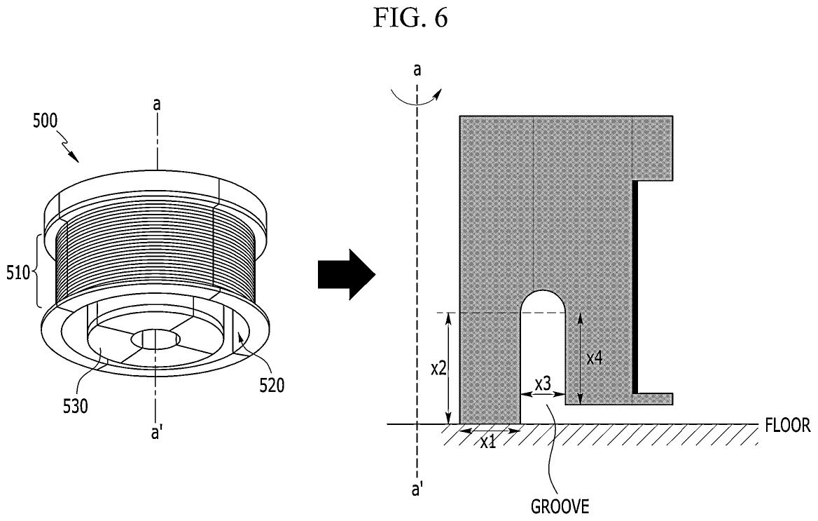

FIG. 6 illustrates an example of an optical fiber spool according to an embodiment.

Referring to FIG. 6, an optical fiber delay-line is provided through an optical fiber spool around which an optical fiber is wound. However, a length of the optical fiber spool may change slightly due to vibration, thereby reducing length stability. Here, a vibration sensitivity is defined as the degree δl/l by which the length of the optical fiber spool changes due to vibration.

To improve laser performance stabilized using the optical fiber delay-line, an optical fiber spool 500 with minimized sensitivity to vibration may be used.

The optical fiber spool 500 includes an optical fiber, and a hollow cylindrical body around which the optical fiber is wound. The optical fiber is wound around an external circumferential surface of the body, and may be wound around a dented winding area 510 of the external circumferential surface. The difference between the height of the winding area 510 and an inner or outer diameter may be determined in consideration of the volumes of an optical fiber and an adhesive. The optical fiber spool 500 has two surfaces oriented in different directions. The surface facing in direction a is an upper surface, while the surface facing in direction a′ is a lower surface that is in contact with the floor. These orientations are defined with respect to the a-a′ axis which is a central axis passing through the hollow space of the spool.

The optical fiber spool 500 is provided with a round groove 520 at a lower end of the body to minimize vibration sensitivity. The groove 520 allows external vibration to be symmetrically transferred to upper and lower parts of the winding area 510 and thus the combined changes in the length of the optical fiber may approximate zero, thereby effectively minimizing the vibration sensitivity.

The groove 520 is formed in a round dented shape, characterized by a width x3 and a height x2 with respect to the central axis at a point spaced a distance x1 from the center of the lower surface of the body.

An inner body of the groove 520 adjacent to the central axis with respect to the groove 520 is in contact with the floor and may be referred to as a floor support part 530. An outer body of the groove 520 distant from the central axis with respect to the groove 520 is elevated at a height of (x2−x4) from the floor. Therefore, vibrations are transferred to the optical fiber spool 500 through the floor support part 530, which is the inner body. However, the outer body of the groove 520, being separated from the floor by a height of (x2−x4), does not directly receive vibrations transferred from the floor.

Even when a force is applied in the same direction, applying a force to the bottom of the object can cause a lateral side of the object to contract, and applying a force to the top of the object can lead to the expansion of the lateral side. For example, when a force is applied to a lower surface of a cylinder in an upward direction (+z-axis direction), the cylinder is pressed and thus a lateral side thereof expands but when the force is applied to an upper surface of the cylinder in the upward direction (+z-axis direction), the cylinder is lifted and thus the lateral side thereof contracts. Thus, in the case of the upper part of the winding area 510, vibration transferred from the floor acts as a force that pushes the lower part of the winding area 510 upward and thus the lateral side of the winding area 510 expands. In contrast, in the case of the lower part of the winding area 510, vibration acts as a force that lifts the upper part of the winding area 510 due to the groove 520 and thus the lateral side of the winding area 510 contracts. As described above, due to the groove 520 causing the lower part of the winding area 510 to be spaced apart from the floor support part 530 and the floor, vibration is transferred to symmetrically act the upper and lower parts of the winding area 510. Here, the vibration that is symmetrically transferred includes vibration causing the relation of the optical fiber and vibration causing the contraction of the optical fiber. Due to the symmetrical transfer of vibration, a part of the optical fiber around the upper part of the winding area 510 expands and a part of the optical fiber around the lower part of the winding area 510 contracts due to the vibration, thus offsetting a change in the total length of the optical fiber.

That is, even when a certain level of vibration sensitivity occurs at each position, the change in the total length of the optical fiber is compensated and thus the vibration sensitivity of the optical fiber spool 500 may significantly decrease.

The position and size of the groove 520 are defined by groove design variables x1, x2, x3, and x4. The groove design variables x=[x1, x2, x3, x4] may be determined based on an object function defined to minimize vibration sensitivity and achieve robust design. Here, because the variable x4 is (x2−separation distance), a distance from the floor may be used as a groove design variable instead of x4. Robust design means minimizing vibration sensitivity errors caused by errors (a processing error, a winding error, etc.) that occur when an optical fiber spool is manufactured.

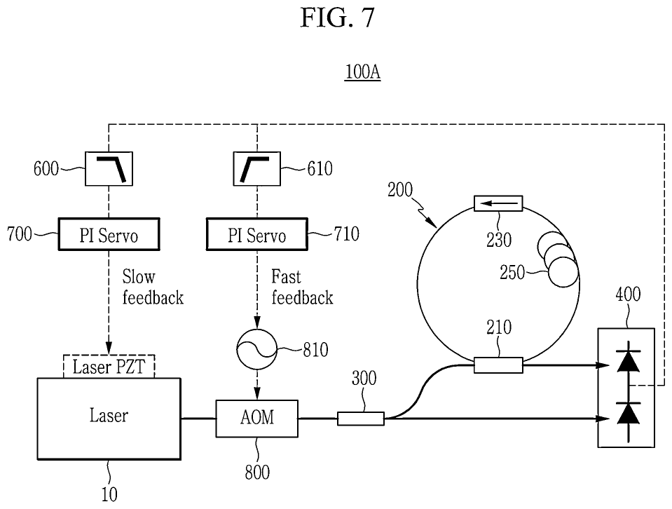

FIG. 7 illustrates an overall configuration of a laser stabilization apparatus according to an embodiment.

Referring to FIG. 7, a laser stabilization apparatus 100A may include an optical fiber ring resonator 200, an optical coupler 300, a balanced photodetector 400, and a feedback controller for transmitting an error signal output from the balanced photodetector 400 to a laser 10.

The feedback controller may be configured variously, and may include, for example, a low-pass filter (LPF) 600 and a servo 700 to transmit the error signal to a piezoelectric transducer (PZT) of the laser 10 for slow frequency correction. A frequency of the laser 10 may be locked by the PZT to which a feedback voltage is applied.

When an output of the laser 10 is modulated by an acousto-optic modulator (AOM) 800, the feedback controller may include a high-pass filter 610 and a servo 710 to transmit the error signal to the AOM 800 for fast frequency correction. A feedback voltage of the servo 710 may be applied to a voltage-controlled oscillator (VCO) 810 to be used for frequency modulation of the AOM 800.

The optical fiber ring resonator 200 may be double-shielded to reduce environmental influences. For example, thermal noise may be reduced by putting the optical fiber resonator 200 in a chamber to which an insulator is attached, and noise caused by ambient sound may be reduced by putting the chamber in a vacuum chamber.

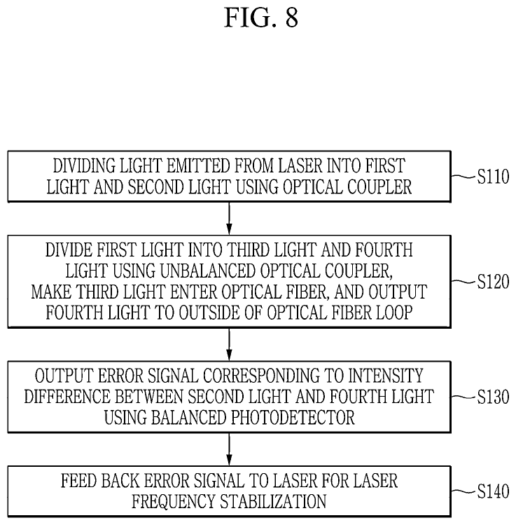

FIG. 8 illustrates an operation method of a laser stabilization apparatus according to an embodiment.

Referring to FIG. 8, the laser stabilization apparatus 100 divides light emitted from a laser into first light and second light, using the optical coupler 300 (S110). The first light may be directed to the optical fiber ring resonator 200 functioning as a frequency discriminator, and the second light may be used as reference light.

The laser stabilization apparatus 100 divides the first light into a third light and a fourth light, using the unbalanced optical coupler 210, makes third light enter an optical fiber loop designed to resonate at a specific frequency, and outputs the fourth light to the outside of the optical fiber loop (S120). The optical fiber loop may include the optical fiber delay-line 250. A length of the optical fiber loop may be designed such that the optical fiber loop may resonate at a frequency that is an integer multiple of a half-wavelength of the laser 10. For example, when the unbalanced optical coupler 210 has a 99:1 coupling ratio, 1% of the first light entering the first port p1 may be divided into third light, which is then directed to the second port p2. When the third light rotates around the optical fiber loop and reaches the fourth port p4, 99% of the third light entering the fourth port p4 is coupled back to the second port p2. Accordingly, a most part of light incident on the optical fiber loop can be stored in the resonator. 99% of the first light entering the first port p1 may be divided into fourth light, which is subsequently outputted to the third port p3.

The laser stabilization apparatus 100 outputs an error signal corresponding to the intensity difference between the second light and the fourth light, using the balanced photodetector 400 (S130). Here, the fourth light transmitted through the optical fiber ring resonator 200 contains not only frequency noise but also other type of noise, such as laser intensity noise. Therefore, instead of directly measuring the fourth light, the frequency noise contained in the fourth light may be detected by using balanced photo detection, which enables cancelling the laser intensity noise contained in both the second light, which is reference light, and the fourth light, which is to be measured. The frequency noise contained in the fourth light may be detected instead of directly measuring the fourth light.

The laser stabilization apparatus 100 feeds back the error signal to the laser 10 for laser frequency stabilization (S140). The detected error signal is associated with a transmittance of the optical fiber ring resonator 200, and thus, when the error signal is fed back to the laser 10, the frequency of the laser 10 may be locked to a frequency at which the transmittance is maintained at a specific value, thereby achieving laser stabilization.

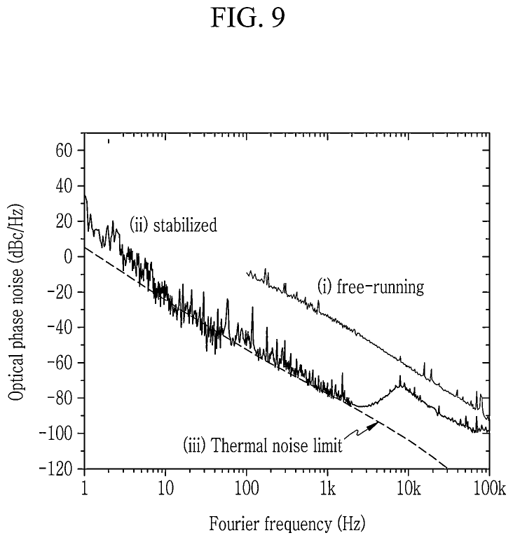

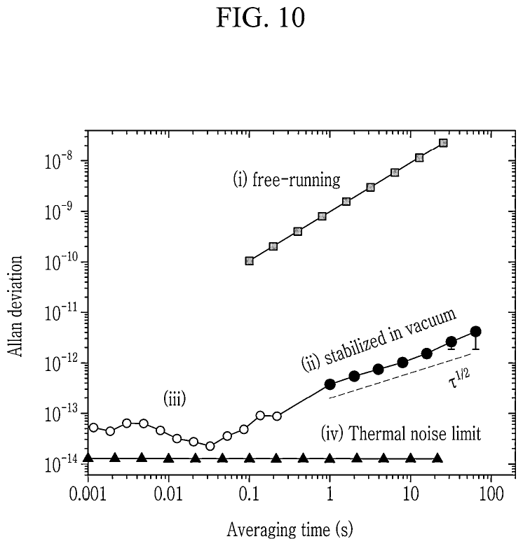

FIG. 9 illustrates a result of measuring phase noise of a stabilized laser according to an embodiment. FIG. 10 illustrates a result of measuring frequency instability of a stabilized laser according to an embodiment.

Referring to FIG. 9, phase noise (see a ‘stabilized’ graph ii) in a laser stabilized by the optical fiber ring resonator 200 is less by about 40 dB than nose in a free running laser (see a ‘free-running’ graph i) that is not stabilized an offset frequency of less than 1 kHz. In addition, a level of thermal noise (see a ‘thermal noise limit graph’ iii) in a 100 m optical fiber, which is an optical reference, is almost reached, thus achieving maximum performance of the optical reference.

Referring to FIG. 10, an Allan deviation obtained by measuring frequency instability of a laser (ii) stabilized using the optical fiber ring resonator 200 is maintained to be a level of about 10⁻¹³ and increased with a slope of τ. Here, the frequency instability may reach 10⁻¹⁴ at 0.03.

As described above, the frequency stabilization apparatus 100 employing the optical fiber ring resonator 200 may be an all-fiber type and thus is alignment-free, so that it can be applied even in a non-laboratory environment. When the system is configured as a free space, optical alignment is prone to misalignment caused by external vibrations or impacts. In contrast, the frequency stabilization apparatus 100 using an optical fiber can operate even in an environment subject to shock and vibration as long as the optical fiber is not broken. The above feature is suitable for fields that require a very stable laser light source in a non-laboratory environment.

The optical fiber ring resonator 200 can be manufactured using only commercially available passive optical fiber components and thus is considerably cheaper than expensive optical cavity-based systems that essentially require vacuum and thermal control systems as well as an expensive cavity, and excellent frequency stabilization performance can be provided.

When frequency stabilization is performed using the optical fiber ring resonator 200, a modulator is not needed for frequency stabilization unlike in the well-known Pound-Drever-Hall (PDH) method or the self-heterodyne method. Accordingly, the size of the frequency stabilization apparatus 100 may be minimized by reducing the sizes of devices therein, and the costs thereof may be reduced.

By using the optical fiber ring resonator 200, the similar Q-factor can be obtained with an optical fiber that is ten times shorter than the self-heterodyne type with respect to the Q-factor. Accordingly, because the Q-factor can be obtained with a short optical fiber, the size of the optical fiber spool can be reduced to significantly reduce the size of a device and manufacturing costs.

The above-described exemplary embodiments can be implemented through not only an apparatus and a method but also a program for execution of functions corresponding to the configurations of the exemplary embodiments or a recording medium storing the program.

While the embodiments of the present disclosure have been described above in detail, the scope of the present disclosure is not limited thereto, and various changes and modifications made by those of ordinary skill in the art on the basis of the basic concepts of the present disclosure defined in the following claims are also within the scope of the present disclosure.

What is claimed is:

1. A laser stabilization apparatus comprising:
an optical fiber resonator which is in the form of an optical fiber loop with an optical fiber delay-line, wherein when light emitted from a laser is input to the optical fiber resonator, a transmittance of the optical fiber resonator changes according to a frequency of the input light; and
a light measurer configured to measure light transmitted through the optical fiber resonator and generate an error signal for stabilizing a frequency of the laser.

2. The laser stabilization apparatus of claim 1, wherein the light measurer comprises a balanced photodetector, and
wherein the balanced photodetector comprises
a first photodiode and a second photodiode, and is configured to measure the intensity difference between target light to be measured, which is input to the first photodiode, and reference light input to the second photodiode, and output the error signal, and
the light emitted from the laser is divided into two components, and one component enters the second photodiode and the other component enters the optical fiber resonator, and light output from the optical fiber resonator enters the first photodiode.

3. The laser stabilization apparatus of claim 2, wherein the balanced photodetector offsets noise contained in both the reference light and the target light, using balanced optical detection, and detects frequency noise of the laser.

4. The laser stabilization apparatus of claim 1, wherein the optical fiber resonator is implemented as a polarization-maintaining fiber.

5. The laser stabilization apparatus of claim 1, wherein the frequency of the laser is locked at a frequency to maintain the error signal at a specific value.

6. The laser stabilization apparatus of claim 1, further comprising
a feedback controller configured to transmit the error signal to a piezoelectric transducer of the laser.

7. The laser stabilization apparatus of claim 1, further comprising
a feedback controller configured to transmit the error signal to a modulator that modulates an output of the laser.

8. A laser stabilization apparatus comprising:
an optical coupler configured to divide light emitted from a laser into first light and second light and output the first light and the second light;
an optical fiber ring resonator configured to divide the first light into third light and fourth light using an unbalanced optical coupler, make the third light entering a ring type optical fiber loop to pass through an optical fiber delay-line of the optical fiber loop, and output the fourth light to outside of the optical fiber loop; and
a balanced photodetector configured to output an error signal corresponding to the intensity difference between the fourth light and the second light,
wherein the error signal is fed back to the laser, and a frequency of the laser is locked at a frequency to maintain the error signal at a specific value.

9. The laser stabilization apparatus of claim 8, wherein the frequency of the laser is determined by a transmittance of the optical fiber ring resonator.

10. The laser stabilization apparatus of claim 8, wherein a Q-factor of the optical fiber ring resonator is calculated, based on a coupling ratio of the unbalanced optical coupler and a length of the optical fiber delay-line.

11. The laser stabilization apparatus of claim 8, wherein the optical fiber ring resonator further comprises
an optical isolator configured to guide light toward a circulation direction in the optical fiber loop.

12. The laser stabilization apparatus of claim 8, wherein the optical fiber ring resonator is implemented as a polarization-maintaining fiber.

13. The laser stabilization apparatus of claim 8, wherein the balanced photodetector comprises
a first photodiode to which the fourth light passing through the optical fiber loop is input and a second photodiode to which the second light is input, and is configured to convert the intensity difference between the fourth light and the second light into an electrical signal, and output the error signal corresponding to the electrical signal.

14. The laser stabilization apparatus of claim 8, wherein the balanced photodetector
offsets noise contained in both the second light and the fourth light using balanced optical detection, and detects frequency noise of the laser.

15. The laser stabilization apparatus of claim 8, further comprising
a feedback controller configured to transmit the error signal to a piezoelectric transducer of the laser.

16. The laser stabilization apparatus of claim 8, further comprising
a feedback controller configured to transmit the error signal to a modulator that modulates an output of the laser.

17. An operation method of a laser stabilization apparatus, comprising:
dividing light emitted from a laser into target light to be measured and reference light;
making light coupled from the target light enter an optical fiber ring resonator, and outputting the transmitting light that is not stored in the optical fiber ring resonator among the target light, to outside of the optical fiber ring resonator; and
outputting an error signal corresponding to the intensity difference between the reference light and the transmitting light output from the optical fiber ring resonator using balanced optical detection,
wherein the optical fiber ring resonator comprises an optical fiber delay-line.

18. The operation method of claim 17, further comprising
feeding back the error signal to the laser for stabilizing the frequency of the laser.

19. The operation method of claim 17, wherein a transmittance of the optical fiber ring resonator changes according to a frequency of input light.

20. The operation method of claim 17, further comprising
offsetting noise contained in both the reference light and the transmitting light output from the optical fiber ring resonator using the balanced optical detection, and detecting frequency noise of the laser.
